(19) United States
(12) Patent Application Publication
(10) Pub. No.: US 2026/0157015 A1
(43) Pub. Date: Jun. 4, 2026

(54) DISPLAY DEVICE

(71) Applicant: LG Display Co., Ltd., Seoul (KR)

(72) Inventors: HeumeIl Baek, Seoul (KR); HoJin Ryu, Goyang-si (KR); Jaemin Park, Ansan-si (KR)

(73) Assignee: LG Display Co., Ltd., Seoul (KR)

(21) Appl. No.: 19/304,481

(22) Filed: Aug. 19, 2025

(30) Foreign Application Priority Data
Nov. 29, 2024 (KR) 10-2024-0175677

(51) Int. Cl. H10H 29/80; H01L 25/075; H10H 20/01; H10H 20/819; H10H 29/34; H10H 29/37; H10H 29/39; H10H 29/41

(52) U.S. Cl. CPC H10H 29/882; H10H 20/819; H10H 29/34; H10H 29/37; H10H 29/39; H10H 29/41; H10H 29/842; H10H 20/034; H10H 20/0363; H10H 20/0364; H10W 90/00

(57) ABSTRACT

A display device includes a substrate, a plurality of reflective electrodes on the substrate, a plurality of bonding layers on the plurality of reflective electrodes, a plurality of light-emitting elements on the plurality of bonding layers and each including a first electrode, a first semiconductor layer on the first electrode, an active layer on the first semiconductor layer, a second semiconductor layer on the active layer, and a second electrode on the second semiconductor layer, a plurality of scattering layers to respectively correspond to the plurality of light-emitting elements, configured to respectively cover the plurality of light-emitting elements, and each having a shape having a cross-section width that decreases upward, and a black bank to contact at least a part of a side surface of each of the plurality of scattering layers and having a shape having a cross-section width that increases upward.

### CROSS-REFERENCE TO RELATED APPLICATIONS

This application claims the priority of and benefits to Korean Patent Application No. 10-2024-0175677 filed on Nov. 29, 2024, in the Korean Intellectual Property Office, the disclosure of which is incorporated herein in its entirety by reference for all purposes, as if fully set forth herein.

### BACKGROUND

### Technical Field

The present disclosure relates to a display device, and more particularly, for example, without limitation, to a display device capable of improving light extraction efficiency and maintaining viewing angle characteristics even though a position of a light-emitting element changes.

Discussion of the Related Art

As display devices used for a monitor of a computer, a TV set, a mobile phone, and the like, there are an organic light-emitting display (OLED) configured to autonomously emit, and a liquid crystal display (LCD) that requires a separate light source.

The range of application of the display devices is diversified from the monitor of the computer and the TV set to personal mobile devices, and studies are being conducted on the display devices having wide display areas and having reduced volumes and weights.

In addition, recently, a display device including a light-emitting diode (LED) has attracted attention as a next-generation display device. Because the LED is made of an inorganic material instead of an organic material, the LED is more reliable and has a longer lifespan than a liquid crystal display device or an organic light-emitting display device. In addition, the LED may be quickly turned on or off, have excellent luminous efficiency, high impact resistance, and great stability, and display high-brightness images.

The description provided in the background section should not be assumed to be prior art merely because it is mentioned in or associated with the background section. The background section may include information that describes one or more aspects of the subject technology.

### SUMMARY

Accordingly, embodiments of the present disclosure are directed to a display device that substantially obviates one or more of the problems due to limitations and disadvantages of the related art.

An aspect of the present disclosure is to provide a display device with improved light extraction efficiency.

Another aspect of the present disclosure is to provide a display device capable of minimizing a luminance deviation with respect to a viewing angle even though a position of a light-emitting element changes.

Still another aspect of the present disclosure is to provide a display device in which a bonding layer corresponding to a light-emitting element is further miniaturized.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises a substrate, a plurality of reflective electrodes disposed on the substrate, a plurality of bonding layers disposed on the plurality of reflective electrodes, a plurality of light-emitting elements disposed on the plurality of bonding layers and each comprising a first electrode, a first semiconductor layer on the first electrode, an active layer on the first semiconductor layer, a second semiconductor layer on the active layer, and a second electrode on the second semiconductor layer, a plurality of scattering layers disposed to respectively correspond to the plurality of light-emitting elements, configured to respectively cover the plurality of light-emitting elements, and each having a shape having a cross-section width that decreases upward, and a black bank configured to contact at least a part of a side surface of each of the plurality of scattering layers and having a shape having a cross-section width that increases upward. Therefore, it is possible to reduce or minimize a change in luminance viewing angle distribution with respect to the transfer position of the light-emitting element.

In another aspect, a display device comprises a substrate, a bonding layer disposed on the substrate, a light-emitting element disposed on the bonding layer and comprising a first electrode, a first semiconductor layer on the first electrode, an active layer on the first semiconductor layer, a second semiconductor layer on the active layer, and a second electrode on the second semiconductor layer, a planarization layer disposed below the active layer and configured to surround a lower portion of the first semiconductor layer, a scattering layer disposed on the planarization layer, configured to cover an upper portion of the first semiconductor layer, the active layer, the second semiconductor layer, and the second electrode, and having a side surface having a shape inclined upward in a direction toward the light-emitting element, and a black bank configured to surround a side surface of a lower portion of the scattering layer and having a side surface having a shape inclined upward in the direction toward the light-emitting element. Therefore, it is possible to reduce or minimize a change in luminance viewing angle distribution with respect to the transfer position of the light-emitting element.

Other detailed matters of the exemplary embodiments are included in the detailed description and the drawings.

In the display device of the present disclosure, the scattering layer may be disposed to cover the upper portion of the light-emitting element, thereby improving the light extraction efficiency.

The light extraction efficiency of the display device of the present disclosure is improved, such that the display device may operate with lower power consumption.

In the display device of the present disclosure, the scattering layer is formed to be higher than the black bank, such that the black bank may be formed in a self-alignment manner without a position error even though a separate patterning process is not performed.

The display device of the present disclosure may reduce or minimize a luminance deviation with respect to the viewing angle.

The effects according to the present disclosure are not limited to the contents exemplified above, and more various effects are included in the present disclosure.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain principles of the disclosure. The above and other aspects, features and other advantages of the present disclosure will be more clearly understood from the following detailed description taken in conjunction with the accompanying drawings, in which:

FIG. 1 is a schematic configuration view of a display device according to an embodiment of the present disclosure;

FIG. 2 is a top plan view of a pixel of the display device according to the exemplary embodiment of the present disclosure;

FIG. 3 is a cross-sectional view taken along line A-A′ in FIG. 2; and

FIGS. 4A to 4G are process diagrams for explaining a method of manufacturing one subpixel of the display device according to the exemplary embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes (e.g., sizes, lengths, widths, heights, thicknesses, locations, radii, diameters, and areas), ratios, angles, numbers, and the like illustrated in the accompanying drawings for describing the exemplary embodiments of the present disclosure are merely examples, and the present disclosure is not limited thereto. Like reference numerals generally denote like elements throughout the disclosure. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

The word “exemplary” is used to mean serving as an example or illustration. Aspects are example aspects. “Embodiments,” “examples,” “aspects,” and the like should not be construed as preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

Components are interpreted to include an ordinary error range even if not expressly stated. Any implementation described herein as an “example” is not necessarily to be construed as preferred or advantageous over other implementations.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

The terms, such as “below,” “lower,” “above,” “upper” and the like, may be used herein to describe a relationship between element(s) as illustrated in the drawings. It will be understood that the terms are spatially relative and based on the orientation depicted in the drawings.

In describing a time relationship, for example, when the temporal order is described as, for example, “after,” “subsequent,” “next,” and “before,” a case which is not continuous may be included unless a more limiting term, such as “just,” “immediate(ly),” or “direct(ly)” is used.

Although the terms “first”, “second”, “A,” “B,” “(a),” and “(b)” and the like are used for describing various components, these components are not confined by these terms. These terms are merely used for distinguishing one component from the other components. Therefore, a first component to be mentioned below may be a second component in a technical concept of the present disclosure.

The term “at least one” should be understood as including any and all combinations of one or more of the associated listed items. For example, the meaning of “at least one of a first element, a second element, and a third element” compasses the combination of all three listed elements, combinations of any two of the three elements, as well as each individual element, the first element, the second element, or the third element.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, a display device according to exemplary embodiments of the present disclosure will be described in detail with reference to accompanying drawings.

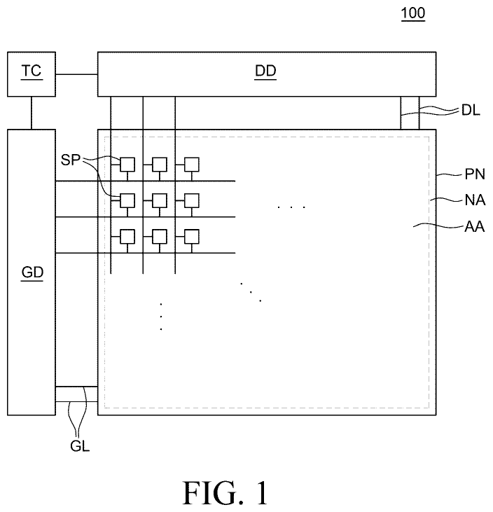

FIG. 1 is a schematic configuration view of a display device according to an exemplary embodiment of the present disclosure.

For convenience of description, FIG. 1 illustrates only a display panel PN, a gate driver GD, a data driver DD, and a timing controller TC among various constituent elements of a display device 100.

With reference to FIG. 1, the display device 100 includes the display panel PN including a plurality of subpixels SP, the gate driver GD configured to supply various types of signals to the display panel PN, and the timing controller TC configured to control the gate driver GD, and the data driver DD.

The gate driver GD supplies a plurality of scan signals to a plurality of scan lines GL in response to a plurality of gate control signals provided from the timing controller TC. FIG. 1 illustrates that the single gate driver GD is disposed to be spaced apart from one side of the display panel PN. However, the number and arrangement of the gate driver GD are not limited thereto. As an example, two gate driver GD may be disposed to be spaced apart from two opposite sides of the display panel PN, without being limited thereto.

The data driver DD converts image data, which is inputted from the timing controller TC, into a data voltage by using a reference gamma voltage in response to a plurality of data control signals provided from the timing controller TC. The data driver DD may supply the converted data voltage to a plurality of data lines DL.

The timing controller TC aligns image data, which is inputted from the outside, and supplies the image data to the data driver DD. The timing controller TC may generate the gate control signals and the data control signals by using synchronizing signals, i.e., dot clock signals, data enable signals, and horizontal/vertical synchronizing signals inputted from the outside. Further, the timing controller TC may control the gate driver GD and the data driver DD by supplying the generated gate control signals and data control signals to the gate driver GD and the data driver DD, respectively.

The display panel PN is configured to display images to a user and includes the plurality of subpixels SP. In the display panel PN, a plurality of scan lines GL and a plurality of data lines DL intersect one another, and each of the plurality of subpixels SP is connected to the scan line GL and the data line DL. In addition, although not illustrated in the drawings, the plurality of subpixels SP may be respectively connected to a high-potential power line, a low-potential power line, a reference line, and the like.

The display panel PN may have a display area AA, and a non-display area NA. As an example, the non-display area NA may be extended from the display area AA. As an example, the non-display area NA may be configured to fully or partially surround the display area AA, without being limited thereto. As an example, the non-display area NA may be partially or fully invisible from a front side of the display panel PN, for example, by being bent toward a rear side of the display panel PN, without being limited thereto. As an example, the non-display area NA may be flat.

The display area AA is an area of the display device 100 in which images are displayed. The display area AA may include the plurality of subpixels SP constituting a plurality of pixels PX, and a circuit configured to operate the plurality of subpixels SP. The plurality of subpixels SP are minimum units that constitute the display area AA. The n subpixels SP may constitute one pixel PX. As an example, n may be an integral number of 1 or more. As an example, the n subpixels SP constituting one pixel PX may emit light of different colors, or at least two of the n subpixels SP may emit light of the same color, without being limited thereto. As an example, the pixels PX may comprise the same number of subpixels SP or varied number of subpixels SP, without being limited thereto. As an example, a light-emitting element, a thin-film transistor for operating the light-emitting element, and the like may be disposed in each of the plurality of subpixels SP, without being limited thereto. The plurality of light-emitting elements may be differently defined depending on the type of the display panel PN. For example, in case that the display panel PN is an inorganic light-emitting display panel PN, the light-emitting element may be a light-emitting diode (LED) or a micro light-emitting diode (micro LED), without being limited thereto.

A plurality of signal lines for transmitting various types of signals to the plurality of subpixels SP are disposed in the display area AA. For example, the plurality of signal lines may include the plurality of data lines DL for supplying data voltages to the plurality of subpixels SP, and the plurality of scan lines GL for supplying gate voltages to the plurality of subpixels SP. The plurality of scan lines GL may extend in one direction in the display area AA and be connected to the plurality of subpixels SP. The plurality of data lines DL may extend in a direction different from one direction in the display area AA and be connected to the plurality of subpixels SP. In addition, a low-potential power line, a high-potential power line, and the like may be further disposed in the display area AA. However, the present disclosure is not limited thereto.

The non-display area NA may be defined as an area in which no image is displayed, i.e., an area extending from the display area AA. As an example, the non-display area NA may include link lines and pad electrodes for transmitting signals to the subpixels SP in the display area AA, without being limited thereto. Alternatively, as an example, the non-display area NA may include drive ICs such as gate driver ICs and data driver ICs, without being limited thereto.

Meanwhile, the non-display area NA may be positioned on a rear surface of the display panel PN, i.e., a surface on which the subpixel SP is not present. Alternatively, the non-display area NA may be excluded. However, the present disclosure is not limited to the configuration illustrated in the drawings.

Meanwhile, the drivers such as the gate driver GD, the data driver DD, and the timing controller TC may be connected to the display panel PN in various ways. For example, the gate driver GD may be mounted in a non-display area NA by a gate-in-panel (GIP) method or mounted between the plurality of subpixels SP by a gate-in-active area (GIA) method in a display area AA. For example, the data driver DD and the timing controller TC may be formed on a separate flexible film and a printed circuit board and electrically connected to the display panel PN by a method of bonding the flexible film and the printed circuit board to a pad electrode formed in the non-display area NA of the display panel PN. In case that the gate driver GD is mounted by the GIP method and the data driver DD and the timing controller TC transmit signals to the display panel PN through the pad electrode in the non-display area NA, it is desirable to ensure an area of the non-display area NA in order to dispose the gate driver GD and the pad electrode, which may increase a bezel.

Alternatively, in case that the gate driver GD is mounted in the display area AA by the GIA method and a side line, which connects a signal line on a front surface of the display panel PN to the pad electrode on the rear surface of the display panel PN, is formed to bond the flexible film and the printed circuit board to the rear surface of the display panel PN, it is possible to reduce or minimize the non-display area NA on the front surface of the display panel PN. As an example, in case that the gate driver GD, the data driver DD, and the timing controller TC are connected to the display panel PN by the above-mentioned method, a zero bezel in which the bezel is not substantially present may be implemented. Embodiments are not limited thereto. As an example, the gate driver GD may be separately formed on a separate film or a separate panel, and electrically connected to the display panel PN, for example, using a tape automated bonding (TAB) method, a chip-on-glass (COG) method, a chip-on-panel (COP) method, or a chip-on-film (COF) method, without being limited thereto.

The plurality of subpixels SP constitutes one pixel. In addition, the plurality of subpixels SP may include the subpixels SP configured to emit light beams with various colors. For example, the plurality of subpixels SP may include red subpixels, green subpixels, and blue subpixels. However, the present disclosure is not limited thereto. The plurality of subpixels SP may further include a subpixel SP configured to emit light with another color, such as white, cyan, magenta, or yellow, etc., without being limited thereto.

As an example, at least some or all of the plurality of subpixels SP may each include two light-emitting elements. In this case, the two light-emitting elements may emit light with the same color. For example, two light-emitting elements configured to emit red light may be disposed in the red subpixel, two light-emitting elements configured to emit green light may be disposed in the green subpixel, and two light-emitting elements configured to emit blue light may be disposed in the blue subpixel. Embodiments are not limited thereto. As an example, at least some or all of the plurality of subpixels SP may each include one light-emitting element, or three or more light-emitting elements. As an example, three or more light-emitting elements may emit light with the same color, without being limited thereto. As an example, the plurality of subpixels SP may each include the same number of light-emitting elements or varied number of light-emitting elements, without being limited thereto.

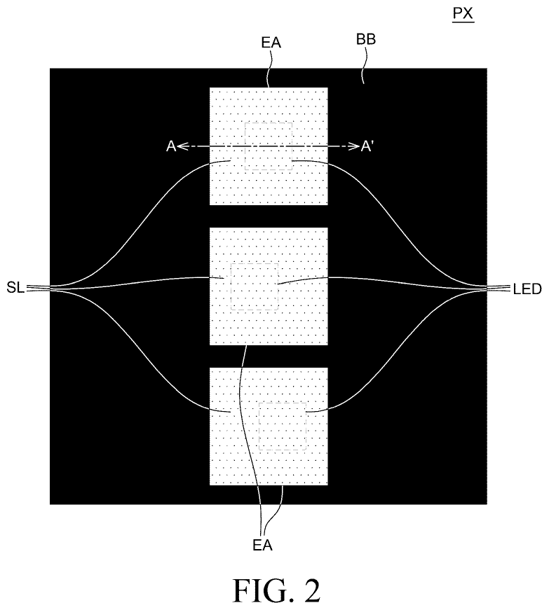

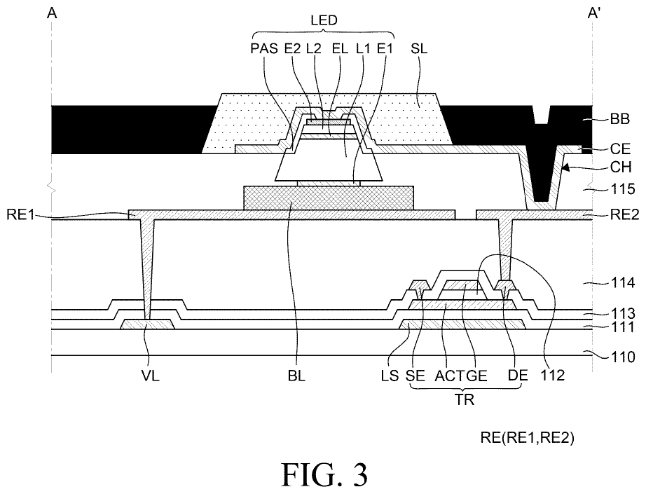

FIG. 2 is a top plan view of the pixel of the display device according to the exemplary embodiment of the present disclosure. FIG. 3 is a cross-sectional view taken along line A-A′ in FIG. 2. For example, FIG. 2 is an enlarged top plan view illustrating a part of the pixel PX of the display device 100 according to the exemplary embodiment of the present disclosure. In addition, FIG. 3 is a cross-sectional view of one subpixel SP of the display device 100 according to the exemplary embodiment of the present disclosure.

With reference to FIGS. 2 and 3 together, the display device 100 according to the exemplary embodiment of the present disclosure may include a substrate 110, a buffer layer 111, a gate insulation layer 112, an interlayer insulation layer 113, a first planarization layer 114, a second planarization layer 115, a plurality of transistors TR, a plurality of light-emitting elements LED, a plurality of bonding layers BL, a plurality of reflective electrodes RE, a power line VL, a connection electrode CE, a plurality of scattering layers SL, and a black bank BB. Embodiments are not limited thereto. As an example, one or more of the above-mentioned components may be omitted, or one or more additional components may be further included.

First, the substrate 110 is a component for supporting various constituent elements included in the display device 100 and may be made of an insulating material. For example, the substrate 110 may be made of glass, resin, or the like, without being limited thereto. In addition, the substrate 110 may include plastic such as polymer and may be made of a material having flexibility, or may be made of a material having rigidity.

A light-blocking layer LS may be disposed on the substrate 110. The light-blocking layer LS blocks light entering an active layer ACT of the transistor TR, which will be described below, from a lower side of the substrate 110. The light-blocking layer LS may block light entering the active layer ACT of the transistor TR, thereby reducing or minimizing a leakage current. As an example, the light-blocking layer LS may at least partially overlap the active layer ACT of the transistor TR, without being limited thereto. As an example, the light-blocking layer LS may be omitted depending on the design.

Further, the power line VL may be disposed on the substrate 110. Specifically, as an example, the power line VL may be disposed on the same layer as the light-blocking layer LS and spaced apart from the light-blocking layer LS, or may be disposed on a different layer from the light-blocking layer LS. In addition, the power line VL may be made of the same material as the light-blocking layer LS. However, the present disclosure is not limited thereto. The power line VL may be a low-potential power line. In this case, a low-potential voltage may be supplied to the power line VL. However, the present disclosure is not limited thereto. The power line VL may be a high-potential power line. In this case, a high-potential voltage may be supplied to the power line VL.

The buffer layer 111 may be disposed on the power line VL and the light-blocking layer LS. The buffer layer 111 may reduce the permeation of moisture or impurities through the substrate 110. For example, the buffer layer 111 may be configured as a single layer or multilayer made of silicon oxide (SiOx) or silicon nitride (SiNx). However, the present disclosure is not limited thereto. However, the buffer layer 111 may be excluded in accordance with the type of substrate 110 or the type of transistor. However, the present disclosure is not limited thereto. The buffer layer 111 may include a contact hole for connecting the power line VL and a first reflective electrode RE1 to be described below.

The plurality of transistors TR may be disposed on the buffer layer 111. The transistor TR may include the active layer ACT, a gate electrode GE, a source electrode SE, and a drain electrode DE.

The active layer ACT may be disposed on the buffer layer 111. The active layer ACT may be made of a semiconductor material such as an oxide semiconductor, amorphous silicon, or polysilicon, a compound semiconductor, an oxide semiconductor, etc. However, the present disclosure is not limited thereto.

The gate insulation layer 112 may be disposed on the active layer ACT. The gate insulation layer 112 is an insulation layer for insulating the active layer ACT and the gate electrode GE. Therefore, the gate insulation layer 112 may be disposed only between the gate electrode GE and the active layer ACT. However, the present disclosure is not limited thereto. For example, a maximum width of the gate insulation layer 112 may be smaller than a maximum width of the active layer ACT. Alternatively, the gate insulation layer 112 may be disposed on the active layer ACT and completely overlap the active layer ACT. Further, the gate insulation layer 112 may be spaced apart from the source electrode SE and the drain electrode DE to be described below. For example, the gate insulation layer 112 may be configured as a single layer or multilayer made of silicon oxide (SiOx) or silicon nitride (SiNx). However, the present disclosure is not limited thereto.

The gate electrode GE may be disposed on the gate insulation layer 112. The gate electrode GE may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The interlayer insulation layer 113 may be disposed on the gate insulation layer 112 and the gate electrode GE. The interlayer insulation layer 113 may include a contact hole for connecting the source electrode SE and the active layer ACT, and/or a contact hole for connecting the drain electrode DE and the active layer ACT. The interlayer insulation layer 113 may be an insulation layer for protecting components disposed below the interlayer insulation layer 113. The interlayer insulation layer 113 may be configured as a single layer or multilayer made of silicon oxide (SiOx) or silicon nitride (SiNx). However, the present disclosure is not limited thereto.

The source electrode SE and the drain electrode DE, which are electrically connected to the active layer ACT, may be disposed on the interlayer insulation layer 113. The source electrode SE and the drain electrode DE may be disposed on the same layer and spaced apart from each other, without being limited thereto. The source electrode SE may be connected to the active layer ACT through the contact hole included in the interlayer insulation layer 113. The drain electrode DE may be connected to the active layer ACT through the contact hole included in the interlayer insulation layer 113. The source electrode SE and the drain electrode DE may each be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The first planarization layer 114 may be disposed on the source electrode SE and the drain electrode DE. The first planarization layer 114 may planarize an upper portion of a pixel circuit including the transistor TR. The first planarization layer 114 may be configured as a single layer or multilayer and made of benzocyclobutene or an acrylic-based organic material, for example. However, the present disclosure is not limited thereto.

The plurality of reflective electrodes RE is disposed on the first planarization layer 114. For example, the plurality of reflective electrodes RE may include the first reflective electrode RE1 and a second reflective electrode RE2. The first reflective electrode RE1 and the second reflective electrode RE2 may be spaced apart from each other.

For example, in one subpixel SP, the first reflective electrode RE1 may overlap the plurality of bonding layers BL and the plurality of light-emitting elements LED. Specifically, a top surface of the first reflective electrode RE1 may contact bottom surfaces of the plurality of bonding layers BL. Meanwhile, the first reflective electrode RE1 may be connected to the power line VL through contact holes of the first planarization layer 114, the interlayer insulation layer 113, and the buffer layer 111. Therefore, the first reflective electrode RE1 may electrically connect the power line VL, the plurality of bonding layers BL, and the plurality of light-emitting elements LED.

The second reflective electrode RE2 may be connected to the transistor TR through a contact hole of the first planarization layer 114. For example, the second reflective electrode RE2 may be connected to the drain electrode DE of the transistor TR. However, the present disclosure is not limited thereto. In addition, the second reflective electrode RE2 may be electrically connected to a second electrode E2 of each of the plurality of light-emitting elements LED through the connection electrode CE to be described below.

The first reflective electrode RE1 and the second reflective electrode RE2 may include various conductive layers in consideration of light reflection efficiency and resistance. For example, the first reflective electrode RE1 and the second reflective electrode RE2 may each be made by using an opaque conductive layer, which is made of silver (Ag), aluminum (Al), molybdenum (Mo), titanium (Ti), or an alloy thereof, together with a transparent conductive layer made of indium tin oxide (ITO). However, the present disclosure is not limited thereto. As an example, although the plurality of reflective electrodes RE are referred to as reflective electrodes, at least one or each the plurality of reflective electrodes may be made of a conductive material with or without a reflective property, without being limited thereto. As an example, the plurality of reflective electrodes RE may be also referred to as an intermediate electrode.

The plurality of bonding layers BL are disposed on the first reflective electrode RE1. The plurality of bonding layers serves to fix the plurality of light-emitting elements LED. Therefore, the plurality of bonding layers BL may be disposed to be spaced apart from one another. Specifically, the plurality of bonding layers BL may be disposed to respectively correspond to the plurality of light-emitting elements LED. Therefore, the plurality of bonding layers BL may serve to fix the plurality of light-emitting elements LED.

As an example, a width of the bonding layer BL may be larger than a maximum width of the light-emitting element LED, without being limited thereto. Therefore, the light-emitting element LED may completely overlap the bonding layer BL. For example, the light-emitting element LED may be provided on the bonding layer BL and disposed inside the bonding layer BL so as not to deviate from the bonding layer BL. Embodiments are not limited thereto. As an example, the width of the bonding layer BL may be equal to or smaller than a maximum width of the light-emitting element LED. As an example, the width of the bonding layer BL may be greater than, equal to or smaller than a maximum width of a first electrode E1 of the light-emitting element LED to be described later, while smaller than a maximum width of the light-emitting element LED, without being limited thereto. As an example, the bonding layer BL may at least partially overlap with the light-emitting element LED or the first electrode E1. As an example, the bonding layer BL may at least partially contact with the light-emitting element LED or the first electrode E1, without being limited thereto. As an example, the light-emitting element LED may be disposed at a central portion of the bonding layer BL, or may deviate from the central portion of the bonding layer BL, without being limited thereto.

The bonding layer BL may include a conductive material. As an example, the bonding layer BL may include a black component and have a black color, without being limited thereto. For example, the conductive material may include carbon. For example, the bonding layer BL may be formed by dispersing a conductive material, which includes carbon, into acrylic resin. However, the present disclosure is not limited thereto. As described above, the bonding layer BL includes a conductive material, such that the first reflective electrode RE1 and a first electrode E1 may be electrically connected.

The plurality of light-emitting elements LED are disposed on the plurality of bonding layers BL. With reference to FIG. 2, the plurality of light-emitting elements LED may be disposed in one pixel PX. In this case, as an example, the plurality of light-emitting elements LED may emit light beams with different colors. For example, in one pixel PX, the plurality of light-emitting elements LED may include a red light-emitting element configured to emit red light, a green light-emitting element configured to emit green light, and a blue light-emitting element configured to emit blue light.

In addition, in a plan view, as an example, at least some of the plurality of light-emitting elements LED may be disposed in the same column. Further, at least some of the plurality of light-emitting elements LED may be disposed to be spaced apart from one another, for example, at equal intervals. However, the present disclosure is not limited thereto. For example, at least some of the plurality of light-emitting elements LED may be disposed to be spaced apart from one another at different intervals.

The light-emitting element LED includes the first electrode E1, a first semiconductor layer L1, an active layer EL, a second semiconductor layer L2, and the second electrode E2.

The first electrode E1 may be disposed on the bonding layer BL and contact the bonding layer BL. For example, a bottom surface of the first electrode E1 may contact a top surface of the bonding layer BL. Therefore, the first electrode E1 may be electrically connected to the power line VL through the bonding layer BL and the first reflective electrode RE1. The first electrode E1 may be a cathode electrode for injecting electrons into the active layer EL. However, the present disclosure is not limited thereto. As an example, the first electrode E1 may serve as a reflective layer that reflects light, which is emitted from the active layer EL, upward, without being limited thereto. The first electrode E1 may be made of an electrically conductive material, for example, a transparent conductive material such as indium tin oxide (ITO) or indium zinc oxide (IZO) or a reflective conductive material such as titanium (Ti), gold (Au), silver (Ag), copper (Cu), or an alloy thereof. However, the present disclosure is not limited thereto.

The first semiconductor layer L1 is disposed on the first electrode E1. The first semiconductor layer L1 may be a layer formed by doping n-type impurities. However, the present disclosure is not limited thereto. For example, the first semiconductor layer L1 may be a layer formed by doping a material, such as gallium nitride (GaN), indium aluminum phosphide (InAlP), or gallium arsenide (GaAs), with n-type impurities. The n-type impurity may be silicon (Si), germanium, tin (Sn), or the like. However, the present disclosure is not limited thereto.

As an example, a width of a bottom surface of the first semiconductor layer L1 may be larger than a width of a top surface of the first electrode E1. Therefore, at least a part of the bottom surface of the first semiconductor layer L1 may be exposed by the first electrode E1. In addition, the exposed bottom surface of the first semiconductor layer L1 may be spaced apart from the top surface of the bonding layer BL by the first electrode E1. Therefore, a side surface of the first electrode E1 may be exposed. Embodiments are not limited thereto. As an example, the width of a bottom surface of the first semiconductor layer L1 may be equal to the width of a top surface of the first electrode E1, without being limited thereto. As an example, the bottom surface of the first semiconductor layer L1 may be not exposed by the first electrode E1, without being limited thereto.

The active layer EL is disposed on the first semiconductor layer L1. The active layer EL emits light by receiving electrons and positive holes from the first semiconductor layer L1 and the second semiconductor layer L2. The active layer EL may be configured as a single layer or a multi-quantum well (MQW) structure. For example, the active layer EL may be made of indium gallium nitride (InGaN), gallium arsenide (GaAs), gallium nitride (GaN), or the like. However, the present disclosure is not limited thereto.

The second semiconductor layer L2 is disposed on the active layer EL. The second semiconductor layer L2 may be a layer formed by doping a particular material with p-type impurities. However, the present disclosure is not limited thereto. For example, the second semiconductor layer L2 may be a layer formed by doping a material, such as gallium nitride (GaN), indium aluminum phosphide (InAlP), or gallium arsenide (GaAs), with p-type impurities. In this case, the p-type impurity may be magnesium, zinc (Zn), beryllium (Be), or the like. However, the present disclosure is not limited thereto.

The second electrode E2 is disposed on the second semiconductor layer L2. The second electrode E2 may be an anode electrode for injecting positive holes into the active layer EL. However, the present disclosure is not limited thereto. The second electrode E2 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

Next, an encapsulation film PAS, which surrounds the first semiconductor layer L1, the active layer EL, the second semiconductor layer L2, and the second electrode E2, may be further disposed. As an example, the encapsulation film PAS may surround the entirety or a portion of the first semiconductor layer L1. As an example, the encapsulation film PAS may surround an upper portion of the first semiconductor layer L1, while exposing a lower portion of the first semiconductor layer L1, without being limited thereto. As an example, the encapsulation film PAS may be spaced apart from the bonding layer BL.

The encapsulation film PAS may be made of an insulating material and protect the first semiconductor layer L1, the active layer EL, and the second semiconductor layer L2. Further, the encapsulation film PAS has a contact hole through which the second electrode E2 is exposed, such that the connection electrode CE to be described below and the second electrode E2 may be electrically connected.

The plurality of light-emitting elements LED of the pixel PX may be disposed on the bonding layer BL and disposed at the same position. Alternatively, the light-emitting elements LED may be disposed on the bonding layer BL and disposed at different positions. For example, with reference to FIG. 2, a center of the light-emitting element LED disposed in a first column, a center of the light-emitting element LED disposed in a second column, and a center of the light-emitting element LED disposed in a third column may not be disposed in the same column.

The second planarization layer 115 may be disposed on the plurality of bonding layers BL and the plurality of reflective electrodes RE. The second planarization layer 115 may planarize upper portions of the first reflective electrode RE1, the second reflective electrode RE2, and the plurality of bonding layers BL disposed below the second planarization layer 115.

The second planarization layer 115 may cover the first reflective electrode RE1, the second reflective electrode RE2, and at least some of the plurality of bonding layers BL. For example, the second planarization layer 115 may cover at least a part of a top surface of each of the plurality of bonding layers BL. In addition, the second planarization layer 115 may cover an entire side surface of each of the plurality of bonding layers BL. Therefore, the second planarization layer 115 may be disposed to surround the plurality of bonding layers BL. The second planarization layer 115 may fill an area in which the bonding layer BL and the first semiconductor layer L1 are spaced apart from each other. At least a part of the second planarization layer 115 may be disposed between the bonding layer BL and the first semiconductor layer L1. Further, as an example, the second planarization layer 115 may contact the exposed side surface of the first electrode E1. As an example, at least a part of the second planarization layer 115 may be disposed between the bonding layer BL and the first semiconductor layer L1 without contacting the exposed side surface of the first electrode E1.

The second planarization layer 115 may be disposed to surround a lower portion of each of the plurality of light-emitting elements LED. For example, the second planarization layer 115 may be disposed to surround at least a part of the side surface of each of the plurality of light-emitting elements LED. In addition, the second planarization layer 115 may contact at least a part of the side surface of the first semiconductor layer L1 exposed by the encapsulation film PAS. The second planarization layer 115 may be positioned to be lower than the active layer EL. Specifically, a top surface of the second planarization layer 115 may be disposed below a bottom surface of the active layer EL. The second planarization layer 115 may include a plurality of contact holes CH for connecting the plurality of connection electrodes CE and the plurality of second reflective electrodes RE2.

For example, the first planarization layer 114 and the second planarization layer 115 may each be made of benzocyclobutene or an acrylic-based organic material. However, the present disclosure is not limited thereto. As an example, the first planarization layer 114 and the second planarization layer 115 may be made of the same material or different materials.

The connection electrode CE may be disposed on the second planarization layer 115. The connection electrode CE may electrically connect the light-emitting element LED and the second reflective electrode RE2. Specifically, one end of the connection electrode CE may be connected to the light-emitting element LED, and the other end of the connection electrode CE may be connected to the second reflective electrode RE2. In this case, the connection electrode CE may be connected to the second reflective electrode RE2 through the contact hole CH of the second planarization layer 115. Therefore, the connection electrode CE may electrically connect the drain electrode DE of the transistor TR and the second electrode E2 of the light-emitting element LED.

The connection electrode CE may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

As an example, the plurality of scattering layers SL are disposed on the connection electrode CE. The plurality of scattering layers SL are disposed to respectively correspond to the plurality of light-emitting elements LED.

As an example, a width of a cross-section of the scattering layer SL decreases upward, without being limited thereto. Therefore, a width of a top surface of the scattering layer SL may be smaller than a width of a bottom surface of the scattering layer SL. In addition, a side surface of the scattering layer SL may have a shape inclined in a direction toward the light-emitting element LED upward. As an example, the width of the top surface of the scattering layer SL may be larger than the width of the bonding layer BL, or may be equal to or smaller than the width of the bonding layer BL, without being limited thereto.

In addition, the scattering layer SL is disposed to cover the light-emitting element LED. Specifically, the scattering layer SL is disposed to cover an upper portion of the light-emitting element LED. The scattering layer SL is disposed to surround a side surface of the upper portion of the light-emitting element LED. Therefore, as an example, a minimum width of the scattering layer SL may be larger than a maximum width of the light-emitting element LED, without being limited thereto. As an example, on the same level, a width of the scattering layer SL may be larger than a width of the light-emitting element LED, without being limited thereto. As an example, on a level higher than the light-emitting element LED, a width of the scattering layer SL may be equal to, smaller than or larger than a maximum width of the light-emitting element LED, without being limited thereto. As an example, the scattering layer SL is disposed to surround a side surface of the upper portion of the light-emitting element LED exposed by the second planarization layer 115. As an example, the scattering layer SL may be in contact with an upper surface of the connection electrode CE and an upper surface of the planarization layer 115, without being limited thereto.

The scattering layer SL is disposed to cover an upper portion of the first semiconductor layer L1, the active layer EL, the second semiconductor layer L2, and the second electrode E2. For example, the scattering layer SL may be disposed to surround a side surface of the upper portion of the first semiconductor layer L1. In addition, the scattering layer SL may be disposed to surround an entire side surface of the second semiconductor layer L2. In this case, the bottom surface of the scattering layer SL may be disposed to be lower than the bottom surface of the active layer EL. Therefore, the scattering layer SL may be disposed to surround an entire side surface of the active layer EL.

The scattering layer SL may overlap a part of the connection electrode CE. Therefore, at least a part of the connection electrode CE may be positioned between the second planarization layer 115 and the scattering layer SL.

The scattering layer SL may cover at least one end of the connection electrode CE. In this case, the other end of the connection electrode CE may extend outward from one end of the scattering layer SL. For example, one end of the scattering layer SL may be disposed outward of one end of the connection electrode CE. In addition, the other end of the scattering layer SL may be disposed on the connection electrode CE. As an example, the scattering layer SL may not overlap the contact hole CH of the second planarization layer 115, without being limited thereto.

With reference to FIG. 2, in one pixel PX, the plurality of scattering layers SL may correspond to the plurality of light-emitting elements LED. For example, the plurality of scattering layers SL may be disposed in the same column and spaced apart from one another. The scattering layer SL may be disposed to cover an entire top surface of the light-emitting element LED. For example, an outer peripheral line of the scattering layer SL may have a shape that surrounds an outer peripheral line of the light-emitting element LED. In addition, in a plan view, the light-emitting element LED may be disposed inside the scattering layer SL. A planar shape of the scattering layer SL may correspond to a planar shape of the light-emitting element LED. However, the present disclosure is not limited thereto. In addition, in a plan view, the light-emitting element LED may be or may not be positioned at a center of the scattering layer SL. For example, in a plan view, a center of the light-emitting element LED and a center of the scattering layer SL may be consistent or may not be consistent with each other. Therefore, the light-emitting element LED may be or may not be positioned at a center of a light-emitting area EA defined by the black bank BB. Embodiment are not limited thereto. As an example, a planar shape of the scattering layer SL may be different from a planar shape of the light-emitting element LED, while the light-emitting element LED may be disposed inside the scattering layer SL, without being limited thereto. As an example, in a plan view, a center of the scattering layer SL may be consistent with a center of the bonding layer BL, without being limited thereto.

The scattering layer SL may include scattering particles. For example, the scattering particles included in the scattering layer SL may include one or more of TiO₂, ZrO₂, Al₂O₃, In₂O₃, ZnO, SnO₂, Sb₂O₃, and ITO. However, the present disclosure is not limited thereto.

The black bank BB is disposed on the second planarization layer 115 and the connection electrode CE. The black bank BB is a constituent element for separating the adjacent subpixels SP. The black bank BB may be disposed so as not to overlap the active layer EL of the light-emitting element LED.

The black bank BB is disposed to contact at least a part of the side surface of each of the plurality of scattering layers SL. In this case, as an example, a height of a top surface of a highest portion of the black bank BB may be lower than a height of the top surface of the scattering layer SL, without being limited thereto. Therefore, as an example, a side surface of the black bank BB may contact a lower portion of the side surface of the scattering layer SL, and an end of a top surface of the black bank BB may contact the side surface of the scattering layer SL. In addition, an upper portion of the side surface of the scattering layer SL may be exposed by the black bank BB. Further, a stepped portion may be formed on a surface of the scattering layer SL and a surface of the black bank BB that contact each other.

As an example, the black bank may have a shape having a width that increases upward, without being limited thereto. Therefore, the side surface of the black bank BB may have a shape inclined upward so that the side surface of the black bank BB becomes closer to the light-emitting element LED. For example, an end of the top surface of the black bank BB may be closer to the light-emitting element LED than an end of a bottom surface of the black bank BB. In addition, the end of the top surface of the black bank BB may be disposed outward of an end of the top surface of the scattering layer SL. Further, the end of the top surface of the black bank BB may be disposed between the end of the top surface of the scattering layer SL and an end of the bottom surface of the scattering layer SL. The end of the top surface of the black bank BB may not overlap the bonding layer BL and the light-emitting element LED.

As an example, the black bank BB may overlap a part of the connection electrode CE, without being limited thereto. In addition, the black bank BB may cover one end of the connection electrode CE. Therefore, the black bank BB may cover at least a part of a top surface of the connection electrode CE. Further, the black bank BB may fill the contact hole CH of the second planarization layer 115. The black bank BB may include a concave portion provided in an area that overlaps the contact hole CH. However, the present disclosure is not limited thereto.

The black bank BB may be made of acrylic-based resin, benzocyclobutene (BCB)-based resin, or polyimide and further include a black component. However, the present disclosure is not limited thereto.

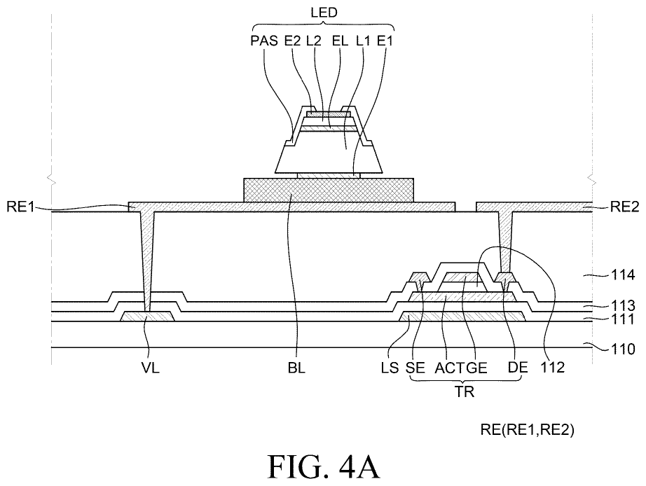

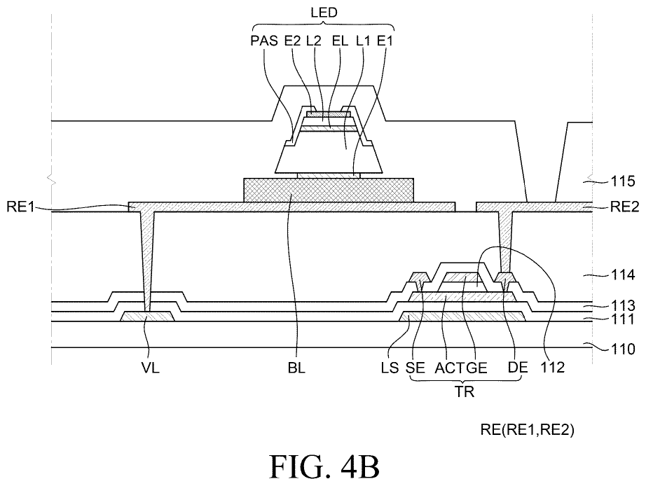

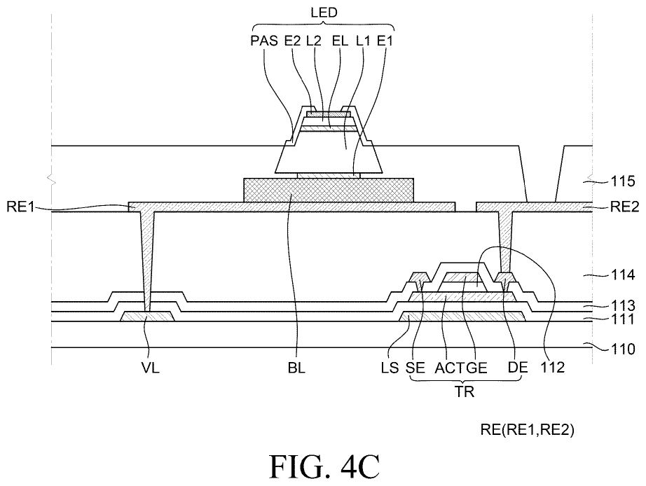

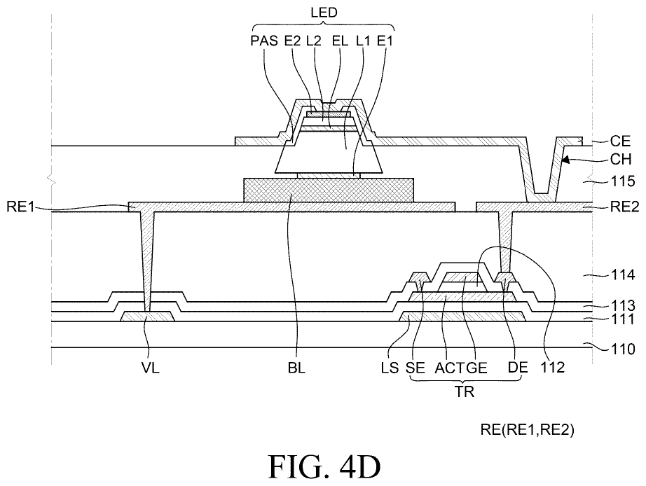

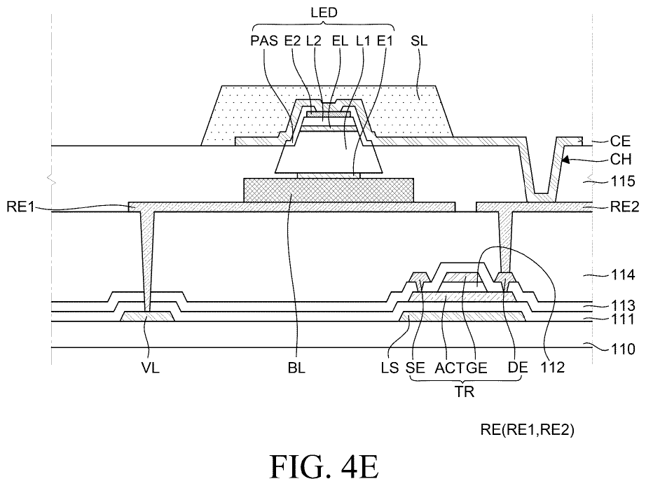

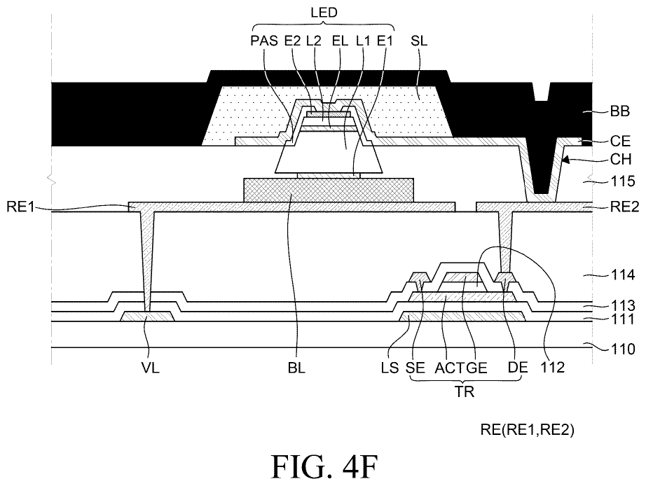

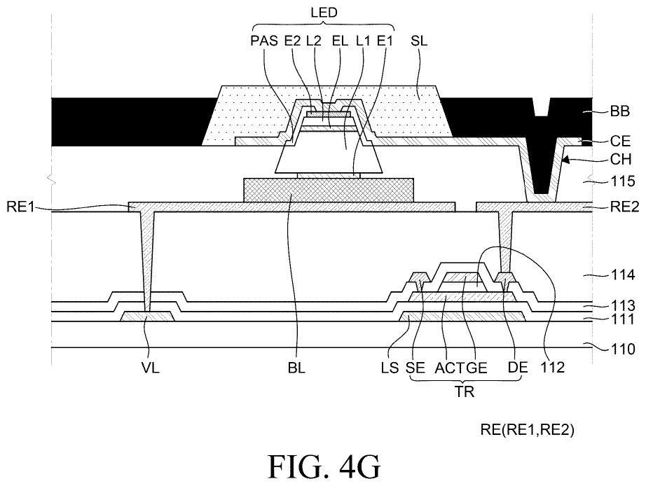

Hereinafter, a method of manufacturing the display device 100 according to the exemplary embodiment of the present disclosure will be described in detail with reference to FIGS. 4A to 4G.

FIGS. 4A to 4G are process diagrams for explaining a method of manufacturing one subpixel of the display device according to the exemplary embodiment of the present disclosure.

First, with reference to FIG. 4A, the first reflective electrode RE1 and the second reflective electrode RE2 may be disposed on the substrate 110. Next, a bonding material for forming the plurality of bonding layers BL may be applied onto the first reflective electrode RE1. In this case, the bonding material may include a conductive material including carbon, without being limited thereto. In addition, the plurality of bonding layers BL may be formed by patterning the applied bonding material. The plurality of light-emitting elements LED may be respectively transferred to the plurality of formed bonding layers BL. In this case, the bonding layer BL may be formed to be wider than the light-emitting element LED.

Meanwhile, during the process of transferring the light-emitting element LED onto the bonding layer BL, the transfer process may be performed on an intended position on the bonding layer BL. However, an alignment error in which the light-emitting elements LED are disposed to deviate from the intended positions may occur. Therefore, as in the example illustrated in FIG. 2, the centers of the plurality of light-emitting elements LED may be positioned in different columns instead of being positioned in the same column. In addition, in another example, the centers of the plurality of light-emitting elements LED may be positioned in different rows instead of being positioned in the same row. As described above, the plurality of light-emitting elements LED may be randomly disposed on the plurality of bonding layers BL. As described above, when an error occurs on the transfer position of the light-emitting element LED, the light-emitting element LED may be transferred to a position that deviates from the bonding layer BL, and a bonding defect of the light-emitting element LED may occur. Therefore, in the display device 100 according to the exemplary embodiment of the present disclosure, the bonding layer BL has a larger width than the light-emitting element LED, such that the light-emitting element LED may be stably transferred onto the bonding layer BL even though an alignment error occurs during the process of transferring the light-emitting element LED.

In addition, in the display device 100 according to the exemplary embodiment of the present disclosure, as an example, the bonding layer BL may include a conductive material including carbon, and the conductive black material may include a black component, without being limited thereto. In addition, the plurality of bonding layers BL may be patterned and disposed while respectively corresponding to the plurality of light-emitting elements LED. As described above, the display device 100 according to the exemplary embodiment of the present disclosure does not include a conductive ball having a relatively large size, such that the sizes of the plurality of bonding layers BL may be further reduced. Therefore, the overall size of the pixel PX including the plurality of bonding layers BL may be reduced. In addition, because the size of the pixel PX is reduced as described above, a larger number of pixels PX may be disposed when the area remains the same, such that the display device 100 with higher resolution may be implemented.

Next, with reference to FIG. 4B, a material for forming the second planarization layer 115 may be applied. In this case, the second planarization layer 115 may be applied to completely cover the light-emitting element LED. Next, a patterning process may be performed to form the contact hole CH that exposes a part of the second reflective electrode RE2. The contact hole CH, through which a part of the second reflective electrode RE2 is exposed, may be formed by the patterning process.

Next, with reference to FIG. 4C, an ashing process may be performed on the second planarization layer 115 to expose the upper portion of the light-emitting element LED. The top surface of the light-emitting element LED may be completely exposed by the ashing process. Specifically, the second electrode E2 may be exposed. In addition, the side surface of the upper portion of the light-emitting element LED may be exposed. In this case, the ashing process is formed so that the height of the top surface of the second planarization layer 115 is lower than the active layer EL, such that the side surface of the active layer EL may not be covered by the second planarization layer. As an example, the height of the top surface of the second planarization layer 115 may be higher than, equal to or lower than the bottom surface of the encapsulation film PAS, without being limited there to. As an example, the side surface of first semiconductor layer L1 may be covered by the encapsulation film PAS or the second planarization layer 115, without being exposed. But the present disclosure is not limited thereto.

Next, with reference to FIG. 4D, the connection electrode CE may be disposed on the second planarization layer 115. In this case, the connection electrode CE may be connected to the second electrode E2 of the light-emitting element LED. In addition, the connection electrode CE may be disposed along the contact hole CH of the second planarization layer 115. Further, the connection electrode CE may be disposed to contact the second reflective electrode RE2 through the contact hole CH of the second planarization layer 115. Therefore, the connection electrode CE may electrically connect the light-emitting element LED and the second reflective electrode RE2.

Next, with reference to FIG. 4E, the scattering layer SL may be disposed on the connection electrode CE and the second planarization layer 115 and cover the plurality of light-emitting elements LED. In this case, the scattering layer SL may be formed by a process of applying a material including a scattering material and then patterning the material, without being limited thereto. The scattering layer SL may be formed to cover the side surface of the upper portion and the top surface of the light-emitting element LED. In addition, the scattering layer SL may be disposed to completely cover the active layer EL of the light-emitting element LED. Meanwhile, the scattering layer SL may be removed by the above-mentioned patterning process from the other areas excluding the area that overlaps the light-emitting element LED. Therefore, the second planarization layer 115 and the connection electrode CE may be partially exposed. In this case, the scattering layer SL may be formed in a tapered shape.

Meanwhile, as described with reference to FIG. 4A, an alignment error may occur during the process of transferring the light-emitting element LED. In this case, there may occur a defect in which the luminance with respect to left and right viewing angles is asymmetric in accordance with the position at which the light-emitting element LED is transferred. For example, in case that the light-emitting element LED is disposed to be biased toward the right side of the bonding layer BL on the cross-section, the luminance at the left side may increase, and the luminance at the right side may decrease, based on the center of the light-emitting element. The difference in luminance may be mitigated by designing a long distance between the light-emitting element LED and the black bank BB. However, when the distance between the light-emitting element LED and the black bank BB is designed to be long, a ratio of an area occupied by the black bank BB to an area of the pixel PX decreases. Further, when the area occupied by the black bank BB decreases, there may occur a problem in that external light reflectance increases.

Therefore, in the display device 100 according to the exemplary embodiment of the present disclosure, the scattering layer SL is formed to surround the top surface and the side surface of the upper portion of the light-emitting element LED. In addition, the scattering layer SL may be disposed to surround the active layer EL. As described above, the scattering layer SL may be disposed to cover the upper portion of the light-emitting element and scatter the light emitted from the light-emitting element LED. Therefore, the light extraction efficiency of the light-emitting element LED may be improved. Furthermore, because the light emitted from the light-emitting element LED scatters in various directions, the dependence on the size of the opening portion of the black bank BB overlapping the light-emitting element LED may be reduced. Therefore, the asymmetry of the luminance viewing angle may be mitigated regardless of the transfer position of the light-emitting element LED.

Meanwhile, both the top surface and the side surface of the light-emitting element may be covered by the scattering layer. However, in case that both the top surface and the side surface of the light-emitting element are covered by the scattering layer, a part of the upper portion of the scattering layer needs to be removed and the second electrode needs to be exposed in order to connect the transistor and the light-emitting element. Next, an additional process of connecting the exposed second electrode and the transistor by means of the connection electrode and covering the top surface of the light-emitting element with the scattering layer is required.

However, in the display device 100 according to the exemplary embodiment of the present disclosure, the lower portion of the light-emitting element LED positioned below the active layer EL is fixed by the second planarization layer 115. In this case, the connection electrode CE for connecting the transistor TR and the second electrode E2 of the exposed light-emitting element LED is firstly disposed, and then the scattering layer SL is disposed on the connection electrode CE. Therefore, in the display device 100 according to the exemplary embodiment of the present disclosure, the scattering layer SL is disposed after the connection electrode CE is disposed. Therefore, it is possible to form the scattering layer SL that covers both the top surface and a part of the side surface of the light-emitting element LED without a separate additional process.

Furthermore, in the display device 100 according to the exemplary embodiment of the present disclosure, the second planarization layer is formed so that the top surface of the second planarization layer 115 is disposed below the active layer EL of the light-emitting element LED. Further, the scattering layer disposed on the second planarization layer 115 may cover the entire active layer EL of the light-emitting element LED. Therefore, the light emitted from the active layer EL toward the side surface may also be scattered. Therefore, the light extraction efficiency of the light-emitting element LED may be further improved. As described above, the light extraction efficiency of the display device 100 according to the exemplary embodiment of the present disclosure is improved, such that the display device 100 may operate with low power consumption.

Next, with reference to FIG. 4F, a material for forming the black bank BB may be applied to completely cover the second planarization layer 115, the connection electrode CE, and the plurality of scattering layers SL. In this case, the material for forming the black bank BB may be applied to completely cover even the top surface of the scattering layer SL.

Lastly, with reference to FIG. 4G, a process of ashing the black bank BB may be performed to expose the top surface of the scattering layer SL. In this case, the ashing process may be performed until the height of the top surface of the black bank BB becomes lower than the height of the top surface of the scattering layer SL. As described above, a part of the side surface of the upper portion and the top surface of the scattering layer SL may be exposed by the process of ashing the black bank BB.

Because the black bank is a constituent element for distinguishing the adjacent subpixels, the black bank may be disposed so as not to overlap the light-emitting element. In this case, the transfer position of the light-emitting element may not be constant each time during the transfer process. In case that the black bank is formed around the light-emitting element regardless of the transfer position of the light-emitting element, the light-emitting element may be consequently disposed to be biased toward one side in the opening portion of the black bank that is the area that overlaps the light-emitting element. As described above, in the case of the light-emitting element disposed to be biased toward one side in the opening portion of the black bank, the luminance with respect to the left and right viewing angles may be asymmetric as described above. Therefore, the opening portion, which exposes the light-emitting element, is formed by applying the material for forming the black bank and then performing a separate precise patterning process in accordance with the position of the transferred light-emitting element.

However, in the display device 100 according to the exemplary embodiment of the present disclosure, the scattering layer SL for covering the light-emitting element LED is formed first, the material for forming the black bank BB is nextly applied, and then the material is simply etched. In this case, the material is etched so that the top surface of the black bank BB is lower than the top surface of the scattering layer SL, such that the black bank BB is formed. That is, a final arrangement position of the black bank BB may be naturally determined by the scattering layer SL regardless of the transfer position of the light-emitting element LED. As described above, in the display device 100 according to the exemplary embodiment of the present disclosure, the black bank BB may be self-aligned without a separate precise patterning process.

The exemplary embodiments of the present disclosure can also be described as follows:

A display device according to an exemplary aspect of the present disclosure comprises a substrate, a plurality of reflective electrodes disposed on the substrate, a plurality of bonding layers disposed on the plurality of reflective electrodes, a plurality of light-emitting elements disposed on the plurality of bonding layers and each comprising a first electrode, a first semiconductor layer on the first electrode, an active layer on the first semiconductor layer, a second semiconductor layer on the active layer, and a second electrode on the second semiconductor layer, a plurality of scattering layers disposed to respectively correspond to the plurality of light-emitting elements, configured to respectively cover the plurality of light-emitting elements, and each having a shape having a cross-section width that decreases upward, and a black bank configured to contact at least a part of a side surface of each of the plurality of scattering layers and having a shape having a cross-section width that increases upward.

A top surface of the black bank may be lower than a top surface of each of the plurality of scattering layers.

The display device may further comprise a planarization layer disposed on the plurality of bonding layers and configured to surround at least a part of a side surface of each of the plurality of light-emitting elements and a plurality of connection electrodes disposed on the planarization layer and connected to the second electrode, wherein the planarization layer may be positioned to be lower than the active layer.

The scattering layer may be disposed on the planarization layer and the plurality of connection electrodes and disposed to surround a side surface of the active layer.

The scattering layer may be disposed to surround a part of an upper portion of the first semiconductor layer and an entire side surface of the second semiconductor layer, and wherein the planarization layer may be disposed to surround a side surface another part of the first semiconductor layer.

The scattering layer may cover at least one end of each of the plurality of connection electrodes.

The plurality of bonding layers may include a conductive black material.

The plurality of light-emitting elements may be randomly disposed on the plurality of bonding layers.

The light-emitting elements, which may be adjacent to one another in a column direction among the plurality of light-emitting elements, may be disposed so that centers thereof are positioned in different columns.

The light-emitting elements, which may be adjacent to one another in a row direction among the plurality of light-emitting elements, may be disposed so that centers thereof are positioned in different rows.

A display device according to another aspect of the present disclosure comprises a substrate, a bonding layer disposed on the substrate, a light-emitting element disposed on the bonding layer and comprising a first electrode, a first semiconductor layer on the first electrode, an active layer on the first semiconductor layer, a second semiconductor layer on the active layer, and a second electrode on the second semiconductor layer, a planarization layer disposed below the active layer and configured to surround a lower portion of the first semiconductor layer, a scattering layer disposed on the planarization layer, configured to cover an upper portion of the first semiconductor layer, the active layer, the second semiconductor layer, and the second electrode, and having a side surface having a shape inclined upward in a direction toward the light-emitting element, and a black bank configured to surround a side surface of a lower portion of the scattering layer and having a side surface having a shape inclined upward in the direction toward the light-emitting element.

A top surface of the black bank may be disposed below a top surface of the scattering layer.

A stepped portion may be formed on a surface of the scattering layer and a surface of the bank that contact each other.

A width of a top surface of the scattering layer may be smaller than a width of a bottom surface of the scattering layer, and the width of the top surface of the scattering layer may be larger than a width of each of the plurality of bonding layers.

The display device may further comprise a transistor disposed below the bonding layer, and a connection electrode configured to electrically connect the transistor and a light-emitting element, wherein the connection electrode may be disposed between the planarization layer and the scattering layer.

The plurality of light-emitting elements may be randomly disposed on the plurality of bonding layers.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a substrate;
a plurality of bonding layers disposed over the substrate;
a plurality of light-emitting elements disposed on the plurality of bonding layers respectively;
a plurality of scattering layers disposed to respectively correspond to the plurality of light-emitting elements, and configured to respectively cover the plurality of light-emitting elements; and
a black bank configured to contact at least a part of a side surface of each of the plurality of scattering layers.

2. The display device of claim 1, wherein a top surface of the black bank is lower than a top surface of each of the plurality of scattering layers.

3. The display device of claim 1, wherein each of the plurality of light-emitting elements comprises a first electrode, a first semiconductor layer on the first electrode, an active layer on the first semiconductor layer, a second semiconductor layer on the active layer, and a second electrode on the second semiconductor layer.

4. The display device of claim 3, further comprising:
a planarization layer disposed on the plurality of bonding layers and configured to surround a part of a side surface of each of the plurality of light-emitting elements; and
a plurality of connection electrodes disposed on the planarization layer and connected to the second electrode,
wherein the planarization layer is positioned to be lower than the active layer.

5. The display device of claim 4, wherein the scattering layer is disposed on the planarization layer and the plurality of connection electrodes and disposed to surround a side surface of the active layer.

6. The display device of claim 5, wherein the scattering layer is disposed to surround an upper portion of a side surface of the first semiconductor layer and an entire side surface of the second semiconductor layer, and
wherein the planarization layer is disposed to surround another portion of the side surface of the first semiconductor layer.

7. The display device of claim 5, wherein each of the plurality of light-emitting elements further comprises an encapsulation film surrounding side surfaces of the active layer, the second semiconductor layer, and the second electrode, and an upper portion of a side surface of the first semiconductor layer, and
wherein the planarization layer is disposed to surround the remaining portion of the side surface of the first semiconductor layer, such that the side surface of first semiconductor layer is covered by the encapsulation film and the planarization layer, without being exposed.

8. The display device of claim 4, wherein the scattering layer is disposed to be in contact with an upper surface of the connection electrode and an upper surface of the planarization layer.

9. The display device of claim 4, wherein the scattering layer covers at least one end of each of the plurality of connection electrodes.

10. The display device of claim 4, wherein a width of a bottom surface of the first semiconductor layer is larger than a width of a top surface of the first electrode, and
at least a part of the planarization layer is disposed between the bonding layer and the first semiconductor layer, to be in contact with an exposed side surface of the first electrode.

11. The display device of claim 1, wherein the plurality of bonding layers includes a conductive black material.

12. The display device of claim 1, wherein each of the plurality of light-emitting elements is randomly disposed on a corresponding bonding layer among the plurality of bonding layers.

13. The display device of claim 12, wherein the light-emitting elements, which are adjacent to one another in a column direction among the plurality of light-emitting elements, are disposed so that centers thereof are positioned in different columns.

14. The display device of claim 12, wherein the light-emitting elements, which are adjacent to one another in a row direction among the plurality of light-emitting elements, are disposed so that centers thereof are positioned in different rows.

15. A display device, comprising:
a substrate;
a bonding layer disposed on the substrate;
a light-emitting element disposed on the bonding layer and comprising a first electrode, a first semiconductor layer on the first electrode, an active layer on the first semiconductor layer, a second semiconductor layer on the active layer, and a second electrode on the second semiconductor layer;
a planarization layer disposed below the active layer and configured to surround a lower portion of the first semiconductor layer;
a scattering layer disposed on the planarization layer, configured to cover an upper portion of the first semiconductor layer, the active layer, the second semiconductor layer, and the second electrode, and having a side surface having a shape inclined in a direction toward the light-emitting element upward; and
a black bank configured to surround a side surface of a lower portion of the scattering layer and having a side surface having a shape inclined in the direction toward the light-emitting element upward.

16. The display device of claim 15, wherein a top surface of the black bank is disposed below a top surface of the scattering layer.

17. The display device of claim 16, wherein a stepped portion is formed on a surface of the scattering layer and a surface of the bank that contact each other.

18. The display device of claim 15, wherein a width of a top surface of the scattering layer is smaller than a width of a bottom surface of the scattering layer, and the width of the top surface of the scattering layer is larger than a width of each of the plurality of bonding layers.

19. The display device of claim 15, further comprising:
a transistor disposed below the bonding layer; and
a connection electrode configured to electrically connect the transistor and a light-emitting element,
wherein the connection electrode is disposed between the planarization layer and the scattering layer.

20. The display device of claim 15, wherein each of the plurality of light-emitting elements is randomly disposed on a corresponding bonding layer among the plurality of bonding layers.
